(19) United States
(12) Patent Application Publication
(10) Pub. No.: US 2003/0022533 A1
(43) Pub. Date: Jan. 30, 2003

(54) Signal transmission connector in a computer hard disk drive

(76) Inventor: Sung-Hyuk Joo, Seoul (KR)

Correspondence Address: MOLEX INCORPORATED, 2222 WELLINGTON COURT, LISLE, IL, 60532, US

(21) Appl. No.: 10/173,187

(22) Filed: Jun. 17, 2002

(30) Foreign Application Priority Data
Jun. 16, 2001 (KR) 2001-34131

(51) Int. Cl. H05K 1/00

(52) U.S. Cl. 439/67

(57) ABSTRACT

Disclosed is a signal transmission connector in a computer hard disk drive wherein connector pins of the signal transmission connector are elastically connected to corresponding contacts of a printed circuit board, thereby reducing the number of components and the cost of the hard disk drive assembly, and reducing the thickness and size of the signal transmission connector and the hard disk drive. In the signal transmission connector, a plurality of connector pins are mounted in pin-holding grooves formed in a pin-holding body. First connection branches of the connector pins are generally planar and are adapted to contact corresponding contacts of a flexible printed circuit board via soldering, and second connection branches of the connector pins are generally C-shaped and adapted to elastically contact corresponding contacts of a printed circuit board. Each of the second connection branches are formed away from the planar connection branches so that each second connection branch is elastically deformed when it comes into contact with the corresponding contacts of the printed circuit board.

### FIELD OF THE INVENTION

The present invention relates to a signal transmission connector in a computer hard disk drive, and more particularly to a connector for electrically interconnecting a printed circuit board and a read-write head of a hard disk drive of a computer.

### BACKGROUND OF THE INVENTION

In general, a connector is an electric device for electrically interconnecting electric wires and circuits and the like, and a signal transmission connector is a connector disposed within a computer hard disk drive for electrically interconnecting a printed circuit board (PCB) and a read-write head of a hard disk drive and for transmitting signals therebetween.

Such a signal transmission connector is connected through its connector pins to the printed circuit board, while being electrically connected to a flexible flat cable (FFC) or a flexible printed circuit board (FPC), which in turn is connected to the read-write head of the hard disk drive. Hereinafter, a conventional socket connector will be described as an example of such a signal transmission connector.

As shown in FIGS. 1 to 4, a signal transmission connector 20 of a conventional computer hard disk drive 10 is disposed in a lower housing 14 of the hard disk drive case, which includes an upper housing 12 and the lower housing 14, and which connector includes a plurality of connector pins 26 adapted to electrically connect to connector pin clampers 32 of a printed circuit board 30 disposed under lower housing 14.

Signal transmission connector 20 is fixed to the upper surface of lower housing 14 by means of screws (not shown) in the state where a flexible flat cable 18 connected to a read-write head 16 of hard disk drive 10 is electrically connected with an upper surface of an upper body 22, and a pin-holding body 24 is inserted in a connector fitting hole 14a formed in lower housing 14. In this state, connector pins 26 of signal transmission connector 20 extend through connector pin holes 34 of printed circuit board 30 disposed under lower housing 14 and are electrically connected with contact portions 32a of connector pin calipers 32.

In the state that signal transmission connector 20 and printed circuit board 30 are disposed on and beneath lower housing 14 as described above, upper housing 12 is assembled on lower housing 14. In this case, the interior space between upper housing 12 and lower housing 14 after they are assembled together is maintained in a vacuum state.

Pin-holding body 24 includes a plurality of pin holes 24a formed therethrough and is integrally formed with the lower surface of upper body 22. Connector pins 26 are mounted in corresponding pin holes 24a to assemble signal transmission connector 20. Signal transmission connector 20 is then fitted in connector fitting hole 14a and a sealing member 40 is fitted around pin-holding body 24 and each connector pin 26, thereby sealing possible gaps around pin-holding body 24 and connector pins 26.

In order to electrically connect the read-write head and the printed circuit board, connector pin calipers for mating to the connector pins and a sealing member having a complicated shape are required in this conventional signal transmission connector. Therefore, a hard disk drive assembly employing the conventional signal transmission connector requires a relatively high number of components, which increases the cost of the hard disk drive assembly.

Further, since the conventional signal transmission connector requires connector pin calipers on the printed circuit board to mate with the connector pins, the process of manufacturing the hard disk drive assembly requires a step of fixing the connector pin calipers to the printed circuit board, which increases the labor and costs associated with the process.

Moreover, in the conventional signal transmission connector, since the connector pins are inserted in the corresponding connector pin calipers to establish electric connection therebetween, the ability to reduce the thickness of the conventional signal transmission connector is reduced. Therefore, it is difficult to manufacture a signal transmission connector having a reduced size, which in turn causes a problem in reducing the size of the hard disk drive.

Furthermore, in a conventional signal transmission connector, the sealing member for sealing gaps around the pin-holding body and the connector pins are sometimes problematic. That is, the complicated shape of the sealing member may cause it to not seal properly and allow pressure to enter the interior space between the upper and lower housing. This seal problem can prevent the interior of the hard disk drive from being maintained in a vacuum state.

### SUMMARY OF THE INVENTION

An object of the present invention therefore is to provide a signal transmission connector for a computer hard disk drive in which connector pins of a signal transmission connector can be electrically connected to corresponding contacts of a printed circuit board through tight contact between them, thereby reducing not only the number of components but also the cost and reliability of the signal transmission connector and the overall hard disk drive assembly.

It is another object of the present invention to provide a signal transmission connector for a computer hard disk drive in which connector pins of the signal transmission connector can be electrically connected to corresponding contacts of a printed circuit board through simple elastic contact between them, so as to reduce the steps of assembling and soldering during the process of manufacturing the hard disk drive assembly, thereby improving the cost-effectiveness of the connector.

It is another object of the present invention to provide a signal transmission connector for a computer hard disk drive in which connector pins of the signal transmission connector can be electrically connected to corresponding contacts of a printed circuit board through simple elastic contact between them, so as to reduce the thickness and size of the signal transmission connector and thereby reduce the size of the hard disk drive.

It is another object of the present invention to provide a signal transmission connector for a computer hard disk drive, in which connector pins of the signal transmission connector are mechanically inserted in pin-holding grooves formed in a pin-holding body, whereby a portion of the upper body is melted by heat fusion and fills in gaps formed between the connector pins and the pin-holding grooves of the pin-holding body, thereby reducing the defective proportion of goods and the manufacturing cost.

In order to accomplish this object, there is provided a signal transmission connector in a computer hard disk drive for electrically connecting a flexible printed circuit and a printed circuit board, the hard disk drive including an upper housing and a lower housing, the signal transmission connector comprising: an upper body disposed on an upper surface of the lower housing, the flexible printed circuit board being disposed above the upper body; a pin-holding body formed integrally with a lower end of the upper body and fitted in a connector fitting hole formed through the lower housing, the pin-holding body having a plurality of pin-holding grooves formed therein; and a plurality of connector pins mounted in the pin-holding grooves, each of the connector pins having a first connection branch and a second connection branch, each first connection branch of each connector pin bing generally planar and extending out of the upper body and adapted to contact corresponding contacts of the flexible printed circuit board, each second connection branch of each connector pin bing generally C-shaped and adapted to elastically contact corresponding contacts of the printed circuit board, each second connection branch being formed away from the planar branch of the connector pin so that the second connection branch is elastically deformed when it comes into contact with the printed circuit board.

The signal transmission connector may further comprise a reference protuberance formed at a portion of a lower surface of the upper body, wherein the reference protuberance is engaged with a reference groove formed at a corresponding portion of the printed circuit board, so as to located the connector on the printed circuit board.

Also, a ring-seating groove may be formed around the pin-holding body integral with the lower end of the upper body, to receive a sealing member therein.

Other objects and advantages of the present invention will be understood from the following description of an electric connector assembly according to a preferred embodiment of the invention in conjunction with the accompanying drawings.

### BRIEF DESCRIPTION OF THE DRAWINGS

The above and other objects, features and advantages of the present invention will be more apparent from the following detailed description taken in conjunction with the accompanying drawings, in which:

FIG. 1 is an exploded perspective view of a conventional computer hard disk drive;

FIG. 2 is a perspective view of a conventional signal transmission connector of the computer hard disk drive shown in FIG. 1;

FIG. 3 is a side view of the signal transmission connector shown in FIG. 2;

FIG. 4 is a sectional view of the signal transmission connector shown in FIG. 2 in its assembled state;

FIG. 5 is an exploded perspective view of a computer hard disk drive employing a signal transmission connector according to the present invention;

FIG. 6 is an exploded perspective view of a signal transmission connector according to the present invention;

FIG. 7 is a perspective view of the signal transmission connector shown in FIG. 6, which is in an assembled state except for a sealing ring of the connector;

FIG. 8 is a plan view of the signal transmission connector shown in FIG. 6;

FIG. 9 is an exploded sectional view of the signal transmission connector, taken along line A-A in FIG. 8;

FIG. 10 is a sectional view of the signal transmission connector in its assembled state, taken along line A-A in FIG. 8;

FIG. 11 is a sectional view of the signal transmission connector in its assembled state, taken along line B-B in FIG. 8;

FIG. 12 is a sectional view of a printed circuit board and a signal transmission connector according to the present invention when they are electrically connected with each other;

FIG. 13 is an exploded side view of the signal transmission connector shown in FIG. 6; and

FIG. 14 is a side view of the signal transmission connector shown in FIG. 6, in its assembled state.

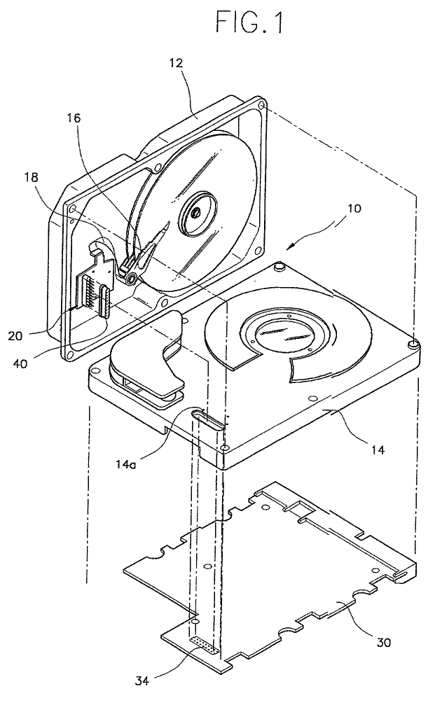

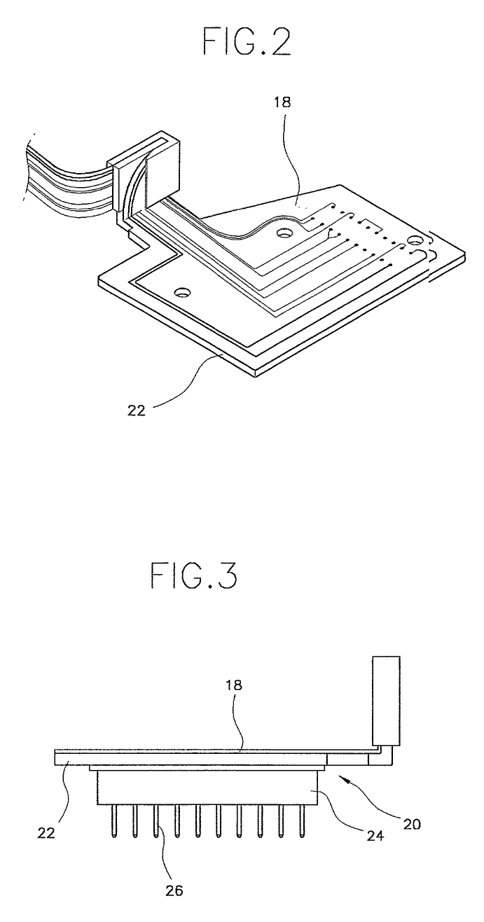

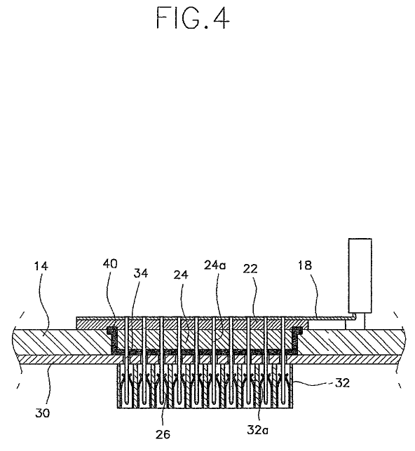

### DETAILED DESCRIPTION OF THE PREFERRED EMBODIMENTS

Hereinafter, a signal transmission connector in a computer hard disk drive according to a preferred embodiment of the present invention will be described with reference to the accompanying drawings.

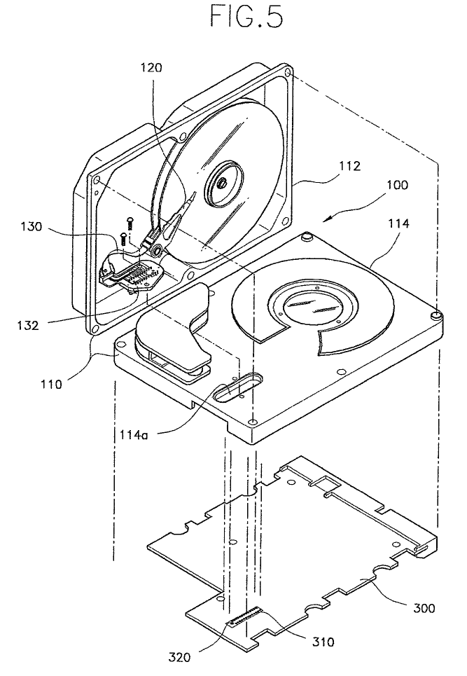

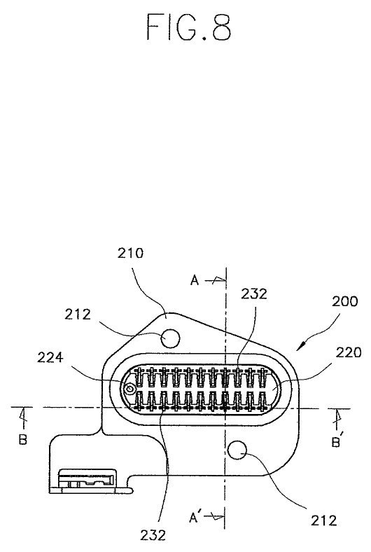

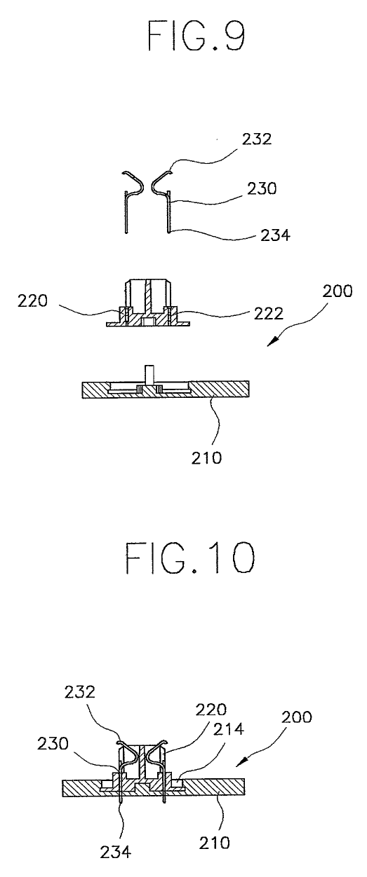

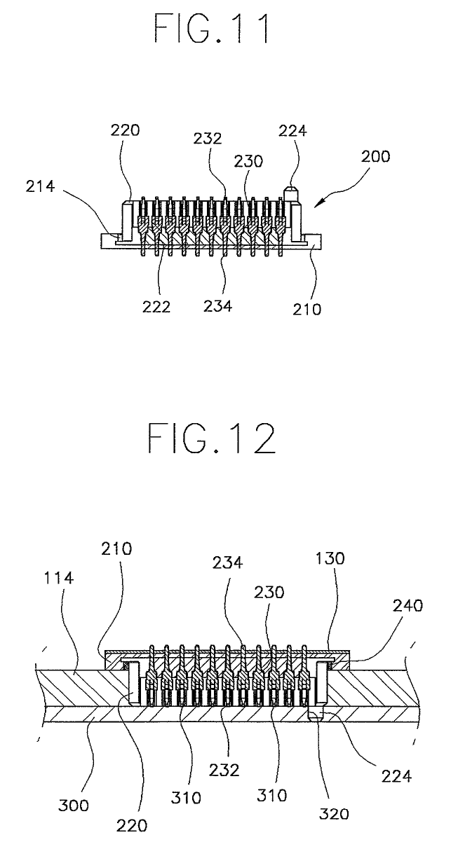

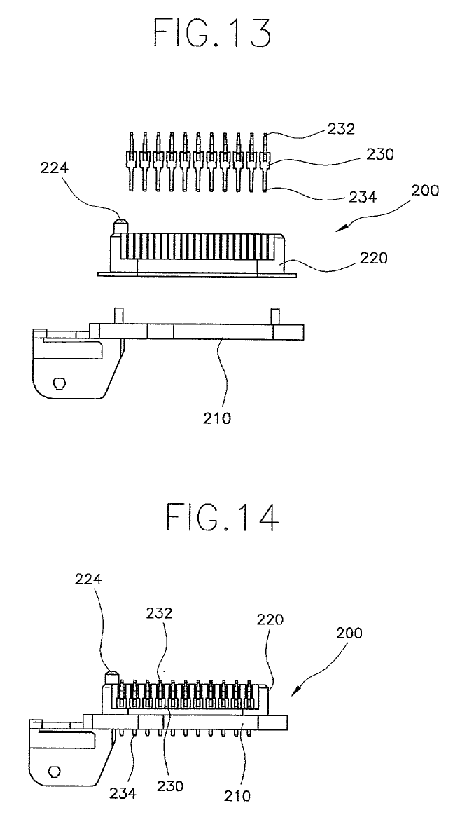

As shown in FIGS. 5 to 14, a signal transmission connector 200 according to the present invention, which is employed in a hard disk drive 100 of a computer, is disposed between an upper housing 112 and a lower housing 114, which constitute a case 110 of hard disk drive 100, and in a portion of lower housing 114, so that connector pins 230 of signal transmission connector 200 can elastically contact and thereby become electrically connected with corresponding contacts 310 of a printed circuit board 300, which is disposed under lower housing 114.

That is to say, signal transmission connector 200 is disposed on lower housing 114 of hard disk drive 100 and printed circuit board 300 is fixed beneath lower housing 114, such that elastic PCB-side connection branches 232 of connector pins 230 come into surface contact with and electrically connect to corresponding contacts 310 of printed circuit board 300.

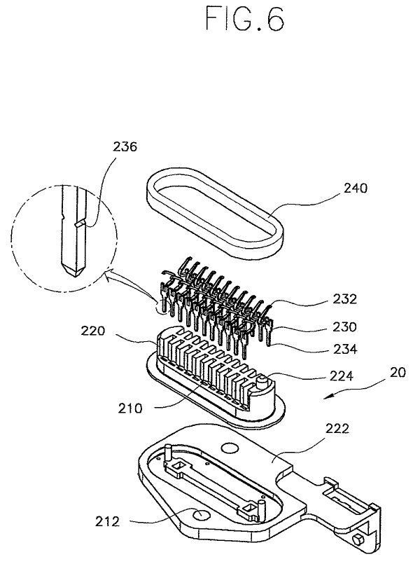

More specifically, and referring to FIGS. 5 and 6, signal transmission connector 200 includes an upper body 210 and a pin-holding body 220 formed integrally with the lower end of upper body 210 and having a plurality of pin-holding grooves 222 formed therein, wherein connector pins 230 are mounted in pin-holding grooves 222. One end of each connector pin 230, which is to be electrically connected with each corresponding contact 310 of printed circuit board 300, is generally C-shaped and is formed away from the planar body of connector pin 230 so that it can be elastically deformed when it comes in contact with a corresponding contact 310 of printed circuit board 300.

In the construction described above, FPC-side connection branches 234 of the connector pins 230 are generally planar and are in line with the planar body of the connector pin and extend through and partially extend outside of the signal transmission connector 200 which forms the upper portion of the signal transmission connector 200. A flexible printed circuit board 130 connected with a read-write head 120 of the hard disk drive 100 is disposed above upper body 210, and corresponding contacts 132 of the flexible printed circuit board 130 are electrically connected with the FPC-side connection branches 234 of connector pins 230, which extend upward beyond upper body 210.

Meanwhile, upper body 210 has screw holes 212 formed through upper body 210. After the signal transmission connector 200 is disposed on lower housing 114 of the case 110, screws are screwed through screw holes 212, so that the signal transmission connector 200 is fixed to lower housing 114. Lower housing 114 also has screw holes formed at predetermined portions of the upper surface of lower housing 114, which can hold the screws fitted through screw holes 212, thereby fixing signal transmission connector 200. In this case, the screw holes formed in lower housing 114 are not through holes but tapped holes.

Pin-holding body 220 is fitted in a connector fitting hole 114a formed through a portion of lower housing 114. Pin-holding body 220 has a plurality of pin-holding grooves 222 extending therethrough and arranged at regular intervals in the longitudinal direction of pin-holding body 220. Middle portions of connector pins 230 are mounted in and held in pin-holding body 220 by pin-holding grooves 222.

Pin-holding body 220 is integrally formed under upper body 210, and a reference protuberance 224 is formed at a portion of the lower surface of pin-holding body 220, corresponding to a reference groove 320 of printed circuit board 300 disposed beneath lower housing 114.

Further, when pin-holding body 220 is fitted in connector fitting hole 114a formed through lower housing 114, a sealing ring 240 is fitted between pin-holding body 220 and connector fitting hole 114a, so as to keep the interior of case 110 in a vacuum state.

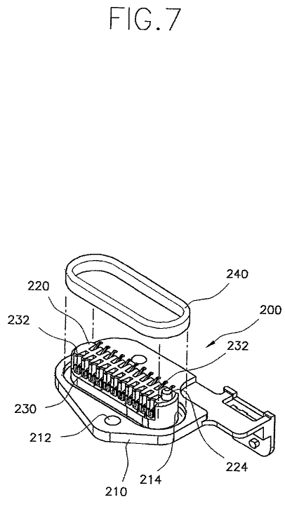

Referring to FIG. 7, sealing ring 240 is disposed at a portion of upper body 210 around pin-holding body 220, so that sealing ring 240 can be seated in upper body 210. When pin-holding body 220 is fitted in connector fitting hole 114a of lower housing 114, sealing ring 240 seated in a ring-seating groove 214 seals the gap between pin-holding body 220 and connector fitting hole 114a, thereby maintaining the interior of case 110 in a vacuum state.

Connector pins 230 electrically interconnect contacts 132 of flexible printed circuit board 130, which is connected with read-write head 120 of case 110, to corresponding contacts 310 of printed circuit board 300, which is disposed beneath lower housing 114. Each of connector pins 230 includes elastic PCB-side connection branch 232, which is in surface contact with and electrically connected to a corresponding contact 310 of printed circuit board 300 disposed beneath lower housing 114, and FPC-side connection branch 234, which is electrically connected to corresponding contact 132 of flexible printed circuit board 130 connected with read-write head 120 of hard disk drive 100.

Referring again to FIG. 6, notches 236 are formed at predetermined portions of each FPC-side connection branch 234 of each connector pin 230, so as to reduce the gap between connector pin 230 and pin-holding groove 222 when connector pin 230 is fixed in pin-holding groove 222 by heat fusion.

During the assembly of connector pins 230 into pin-holding grooves 222 of pin-holding body 220, connector pins 230 are first inserted in pin-holding grooves 222 through a mechanical assembly. Then, in a state where the upper portion of pin-holding body 220 in which connector pins 230 are inserted is located under upper body 210, connector pins 230 are formed integrally in pin-holding grooves 222 through heat fusion. In this case, a portion of the lower portion of upper body 210 that melts during the heat fusion fills in a groove having a predetermined shape, which is formed inside of the upper portion of pin-holding body 220, thereby preventing gaps from being formed between connector pins 230 and pin-holding grooves 222. Note that FPC-side connection branches 234 of connector pins 230 partially extend above upper body 210 during the heat fusion process.

In the meantime, each C-shaped elastic PCB-side connection branch 232 of each connector pin 230 is formed from the planar body of connector pin 230 so that the elastic PCB-side connection branch 232 can be elastically deformed to a certain degree when the elastic PCB-side connection branch 232 is in surface contact with corresponding contact 310 of printed circuit board 300. This elastically deformable construction of PCB-side connection branches 232 enables PCB-side connection branches 232 to be in close contact with corresponding contacts 310 of printed circuit board 300 by the elastic force when elastic PCB-side connection branches 232 are in surface contact with corresponding contacts 310 of printed circuit board 300. That is, when elastic PCB-side connection branches 232 of connector pins 230 are elastically deformed by external force applied thereto, the restoring force of elastic PCB-side connection branches 232 forces elastic PCB-side connection branches 232 into tight contact with corresponding contacts 310 of printed circuit board 300.

Hereinafter, a process of assembling signal transmission connector 200 according to the present invention with hard disk drive 100 will be described. First, flexible printed circuit board 130 connected with read-write head 120 of hard disk drive 100 is located above upper body 210 of signal transmission connector 200, and FPC-side connection branches 234 of connector pins 230 protruding upward out of upper body 210 of signal transmission connector 200 are electrically connected with corresponding contacts 132 of flexible printed circuit board 130 by soldering.

After flexible printed circuit board 130 is electrically connected with FPC-side connection branches 234 of connector pin 230 as described above, sealing ring 240 is fitted in ring-seating groove 214 around pin-holding body 220 of signal transmission connector 200, and pin-holding body 220 with sealing ring 240 is fitted in connector fitting hole 114a formed through lower housing 114. Thereafter, screws are screwed through screw holes 212 into screw holes of lower housing 114, so that signal transmission connector 200 is assembled on lower housing 114.

In the meantime, printed circuit board 300 is located beneath lower housing 114 and is fixed to lower housing 114 by means of screws. In this case, reference protuberance 224 of pin-holding body 220 is fitted in reference groove 320 of printed circuit board 300.

By locating signal transmission connector 200 and printed circuit board 300 on and beneath lower housing 114 and assembling them with lower housing 114 by means of screws, signal transmission connector 200 and printed circuit board 300 can be tightly assembled with lower housing 114.

In the course of fastening signal transmission connector 200 and printed circuit board 300 on and beneath lower housing 114 by means of screws as described above, elastic PCB-side connection branches 232 of connector pin 230 of signal transmission connector 200 can be more tightly in contact and electrically connected with corresponding contacts 310 of printed circuit board 300.

Hereinafter, described will be a method of manufacturing signal transmission connector 200 according to the present invention, which has the construction described above. First, as shown in FIGS. 6, 9 and 13, upper body 210, which forms the upper portion of signal transmission connector 200, and pin-holding body 220 having pin-holding grooves 222, in which connector pins 230 are inserted and fixed, are separately formed by molding.

Then, connector pins 230 are mounted in pin-holding grooves 222 through a mechanical assembly, and pin-holding body 220 with connector pins 230 is located under upper body 210 (integral with upper body 210) by heat fusion.

In the course of attaching pin-holding body 220 and connector pins 230 with each other by heat-fusing upper body 210 with pin-holding body 220 after mechanically inserting and fitting connector pins 230 in pin-holding grooves 222, the lower portion of upper body 210 comes to surround the upper portion of pin-holding body 220 and the melted portion of upper body 210 is filled in a predetermined groove (not shown) formed at the upper portion of pin-holding body 220, so that pin-holding body 220 and connector pin 230 can be manufactured as a single body.

By making pin-holding body 220 and upper body 210 a single unit through heat fusion (an overmold injection molding) after mounting connector pins 230 in pin-holding grooves 222, a portion of the lower portion of upper body 210 is melted and filled between connector pins 230 and pin-holding grooves 222 of pin-holding body 220, so as to prevent gaps from being formed therebetween.

Accordingly, in a signal transmission connector of a computer hard disk drive according to the present invention, connector pins of the signal transmission connector are electrically connected with corresponding contacts of the printed circuit board through tight contact between them, thereby reducing not only the number of components but also the cost of the printed circuit board and the signal transmission connector.

Further, a signal transmission connector of a computer hard disk drive according to the present invention can reduce the steps of assembling and soldering in the process of manufacturing the hard disk drive assembly, and improving the reliability of the assembly by enabling connector pins of the signal transmission connector to be electrically connected with corresponding contacts of the printed circuit board through simple elastic contact between them.

Moreover, according to the present invention, the thickness and size of the signal transmission connector can be reduced, and the size of the hard disk drive can be correspondingly reduced, by enabling connector pins of the signal transmission connector to be electrically connected with corresponding contacts of the printed circuit board through simple elastic contact between them.

Furthermore, in the disclosed signal transmission connector, connector pins of the signal transmission connector are mechanically inserted in pin-holding grooves formed in a pin-holding body, pin-holding body with the connector pins is located under upper body, and then a portion of upper body is melted by heat fusion and is filled in a groove formed between the connector pins and the pin-holding body during the assembling, so as to prevent gaps from being formed between the connector pins and the pin-holding grooves of pin-holding body.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A signal transmission connector in a hard disk drive for electrically connecting a flexible printed circuit and a printed circuit board, the hard disk drive including an upper housing and a lower housing, the signal transmission connector comprising:
an upper body disposed on an upper surface of the lower housing, the flexible printed circuit board being disposed above the upper body;
a pin-holding body formed integrally with a lower end of the upper body and adapted to be fitted in a connector fitting hole formed in the lower housing, the pin-holding body having a plurality of pin-holding grooves formed therein; and
a plurality of connector pins mounted in the pin-holding grooves, each of the connector pins having a first connection branch and a second connection branch, each first connection branch of each connector pin being generally planar and extending out of the upper body and adapted to contact corresponding contacts of the flexible printed circuit board, each second connection branch of each connector pin being generally C-shaped and adapted to elastically contact a corresponding contact of the printed circuit board, each second connection branch being formed away from the planar portion of the connector pin so that each second connection branch is elastically deformed when it contacts the corresponding contact of the printed circuit board.

2. A signal transmission connector as claimed in claim 1, wherein each first connection branch of each connector pin is adapted to contact corresponding contacts of the flexible circuit board by soldering.

3. A signal transmission connector as claimed in claim 1, further comprising a reference protuberance formed on a portion of a lower surface of the upper body, wherein the reference protuberance is adapted to engage a reference groove formed in a corresponding portion of the printed circuit board.

4. A signal transmission connector as claimed in claim 1, further comprising a ring-seating groove formed around the pin-holding body and integral with the lower end of the upper body, and a sealing member adapted to be seated in the ring-seating groove.
